(19) United States
(12) Patent Application Publication
(10) Pub. No.: US 2024/0341085 A1
(43) Pub. Date: Oct. 10, 2024

(54) SEMICONDUCTOR STRUCTURE AND MANUFACTURING METHOD THEREFOR

(71) Applicant: ICLEAGUE TECHNOLOGY CO., LTD., Jiaxing, Zhejiang (CN)

(72) Inventors: Wenyu HUA, Jiaxing (CN); Zhi ZHANG, Jiaxing (CN)

(73) Assignee: ICLEAGUE TECHNOLOGY CO., LTD., Jiaxing, Zhejiang (CN)

(21) Appl. No.: 18/575,998

(22) PCT Filed: Feb. 7, 2022
(86) PCT No.: PCT/CN2022/075385

§ 371 Date: Jan. 2, 2024

(30) Foreign Application Priority Data
Jan. 21, 2022 (CN) 202210074368.7

(51) Int. Cl. H10B 12/00

(52) U.S. Cl. CPC H10B 12/482; H10B 12/05; H10B 12/33

(57) ABSTRACT

A semiconductor structure and a manufacturing method include providing a substrate with a first surface and a second surface, which are opposite each other; from the first surface of the substrate, forming a transistor array having a plurality of transistors; thinning the substrate from the second surface until a first end of a conductive channel of each transistor is exposed, wherein the first end is the end of the conductive channel that is close to the second surface; forming an insulating layer, which covers at least part of the first end of the conductive channel, such that a first width of the exposed first end of the conductive channel is less than a second width of the conductive channel; and forming a bit line structure, which covers the exposed part of the first end of the conductive channel.

### CROSS-REFERENCE TO RELATED APPLICATIONS

The application is based on and claims priority to Chinese Patent Application No. 202210074368.7 filed on Jan. 21, 2022 and entitled “SEMICONDUCTOR STRUCTURE AND MANUFACTURING METHOD THEREFOR”, the entire contents of which are incorporated herein by reference in its entirety.

### TECHNICAL FIELD

Embodiments of the disclosure relate to the field of semiconductor technologies, and relate to, but are not limited to, a semiconductor structure and a manufacturing method therefor.

### BACKGROUND

The process of a Vertical Channel Array Transistor (VCAT) architecture is carried out on the backside of a thinned array wafer, and a bit line is required to be aligned with the lower end of an active region. In the case where an array wafer is affected by physical factors such as heat, local stress, overall warping, carrier wafer, bonding, there is a problem of overall warping and local stress, which affects the alignment between the bit line on the backside and the active region, thereby resulting in alignment failure. The alignment failure between the bit line and the source has become a problem that needs to be solved urgently.

### SUMMARY

In view of the above, embodiments of the disclosure provide a semiconductor structure and a manufacturing method therefor.

In a first aspect, embodiments of the disclosure provide a method for manufacturing a semiconductor structure. The method includes the following operations.

A substrate is provided. The substrate has a first surface and a second surface that are opposite to each other.

A transistor array positioned in the substrate is formed from the first surface of the substrate. The transistor array includes multiple transistors, and a height of the transistor is less than a thickness of the substrate.

The substrate is thinned from the second surface until a first end of a conductive channel of the transistor is exposed. The first end is an end, which is close to the second surface, of the conductive channel.

An insulation layer covering at least a portion of the first end of the conductive channel is formed, such that a first width of an exposed portion of the first end of the conductive channel is less than a second width of the conductive channel.

A bit line structure covering the exposed portion of the first end of the conductive channel is formed.

In some embodiments, a dielectric layer may be filled between the multiple transistors. The operation of forming the insulation layer covering at least the portion of the first end of the conductive channel may include the following operations.

After the substrate is thinned, a portion of the conductive channel is continued to be etched from the first end of the conductive channel, to form multiple recessed structures between the dielectric layers.

The insulation layer is formed on a sidewall of the recessed structure, such that the insulation layer covers at least the portion of the first end of the conductive channel to form a trench with a sidewall covered by the insulation layer.

In some embodiments, the operation of forming the insulation layer on the sidewall of the recessed structure may include the following operations.

A bottom surface and the sidewall of the recessed structure are covered by an insulation material.

The insulation material covering the bottom surface of the recessed structure is removed to form the insulation layer covering the sidewall of the recessed structure.

In some embodiments, there may be a word line structure of the transistor between two adjacent conductive channels. The word line structure is positioned in a region of the recessed structure, and a depth of the recessed structure positioned on the word line structure is less than a depth of the recessed structure positioned on the conductive channel.

The operation of forming, in the recessed structure, the insulation layer covering at least the portion of the first end of the conductive channel may further include the following operation.

The insulation layer covering a portion of the word line structure and covering at least the portion of the first end of the conductive channel is formed in the recessed structure.

In some embodiments, the operation of forming the bit line structure covering the exposed portion of the first end of the conductive channel may include the following operation.

A conductive material is deposited in the trench to form the bit line structure. A width of the trench is equal to the first width.

In some embodiments, the method may further include the following operations.

A carrier wafer is provided.

The first surface of the substrate and the carrier wafer are bonded.

In some embodiments, the operation of thinning the substrate from the second surface until the first end of the conductive channel of the transistor is exposed may include the following operations.

The carrier wafer and the substrate are flipped, such that the second surface is vertically upward.

The substrate is thinned from the second surface until the first end of the conductive channel of the transistor is exposed.

In some embodiments, the method may further include the following operation.

A storage capacitor connected to the transistor is formed on the first surface of the substrate.

In some embodiments, the method may further include the following operations.

A drain is formed at the first end of the conductive channel.

A source is formed at a second end of the conductive channel. The second end is an end, which is close to the first surface, of the conductive channel.

In a second aspect, embodiments of the disclosure provide a semiconductor structure. The semiconductor structure includes a substrate, a transistor array, an insulation layer, and a bit line structure.

The substrate has a first surface and a second surface that are opposite to each other.

The transistor array is positioned in the substrate. The transistor array includes multiple transistors.

The insulation layer covers at least a portion of a first end of a conductive channel, such that a first width of a portion of the first end of the conductive channel, which is not covered by the insulation layer, is less than a second width of the conductive channel. The first end is an end, which is close to the second surface, of the conductive channel.

The bit line structure is connected to the portion of the first end of the conductive channel, which is not covered by the insulation layer.

In some embodiments, the semiconductor structure may further include dielectric layers and multiple recessed structures.

The dielectric layers are positioned between the multiple transistors.

The multiple recessed structures are positioned between the dielectric layers.

In some embodiments, the insulation layer may be positioned on a sidewall of the recessed structure, the insulation layer may cover at least the portion of the first end of the conductive channel, and the recessed structure with the sidewall covered by the insulation layer may be a trench.

In some embodiments, the bit line structure may be positioned in the trench, and a width of the trench may be equal to the first width.

In some embodiments, the semiconductor structure may further include a word line structure of the transistor.

The word line structure is positioned between two adjacent conductive channels, the word line structure is positioned in a region of the recessed structure, and a depth of the recessed structure positioned on the word line structure is less than a depth of the recessed structure positioned on the conductive channel.

In some embodiments, the semiconductor structure may further include a storage capacitor.

The storage capacitor is positioned on the first surface of the substrate and connected to the transistor.

In some embodiments, the first end of the conductive channel may include a drain of the transistor.

A second end of the conductive channel may include a source of the transistor, and the second end is an end, which is close to the first surface, of the conductive channel.

According to the embodiments of the disclosure, the size of the bit line channel is reduced by a sidewall deposition/etching process after etching backing a backside substrate, thereby reducing the key size of a bit line, reducing the parasitic capacitance between the bit lines, and improving reading performance of a transistor. Furthermore, the bit line structure in the embodiments of the disclosure is formed directly on the bit line structure, which will not result in alignment failure due to the overall warping and local stress of the substrate. The probability of alignment failure between the bit line and the source is reduced.

### BRIEF DESCRIPTION OF THE DRAWINGS

FIGS. 1A-ID are schematic diagrams of semiconductor structures in some embodiments.

FIG. 2 is a flowchart of a method for manufacturing a semiconductor structure provided by embodiments of the disclosure.

FIG. 3A is a structural schematic diagram of a substrate provided by embodiments of the disclosure.

FIG. 3B is a top view of a transistor array provided by embodiments of the disclosure.

FIG. 3C is a top view of another transistor array provided by embodiments of the disclosure.

FIG. 3D is a sectional view of a transistor array provided by embodiments of the disclosure.

FIG. 4A is a top view of a transistor array provided by embodiments of the disclosure.

FIG. 4B is a top view of another transistor array provided by embodiments of the disclosure.

FIGS. SA-SB are schematic diagrams of forming a recessed structure in a method for manufacturing a semiconductor structure provided by embodiments of the disclosure.

FIGS. 6A-6B are schematic diagrams of forming a trench in a method for manufacturing a semiconductor structure provided by embodiments of the disclosure.

FIGS. 7A-7B are schematic diagrams of forming a bit line structure in a method for manufacturing a semiconductor structure provided by embodiments of the disclosure.

FIG. 8 is a sectional view of a recessed structure in a semiconductor structure provided by embodiments of the disclosure.

FIG. 9 is a schematic diagram of forming a storage capacitor in a semiconductor structure provided by embodiments of the disclosure.

FIG. 10 is a schematic diagram of forming a source and a drain in a semiconductor structure provided by embodiments of the disclosure.

FIGS. 11 to 15B are schematic diagrams of a formation process of a semiconductor structure.

FIGS. 16A to 20B are schematic diagrams of a formation process of a semiconductor structure provided by embodiments of the disclosure.

Substrate—200; carrier wafer—201; transistor—300; conductive channel—301; insulation layer—302; bit line structure—303; dielectric layer—304; recessed structure—305; trench—306; word line structure—307; isolation layer—309; capacitor—310; drain—311; source—312; polysilicon layer—313; metal silicide layer—314; metal layer—315; conductive plug—316; air trench—317.

### DETAILED DESCRIPTION

In order to facilitate understanding of the disclosure, exemplary implementation manners of the disclosure will be described in detail with reference to the relevant drawings. Although exemplary implementation manners of the disclosure are shown in the drawings, it should be understood, however, that the disclosure may be realized in various forms and should not be limited by the specific implementation manners set forth herein. Conversely, these implementation manners are provided to enable a more thorough understanding of the disclosure and to enable a complete communication of the scope of the disclosure to those skilled in the art.

In the following description, a great deal of specific detail is provided in order to provide a more thorough understanding of the disclosure. However, it will be apparent to those skilled in the art that the disclosure may be implemented without one or more of these details. In some embodiments, some technical features that are well known in the art are not described in order to avoid confusion with the disclosure. That is, here, it is possible not to describe all of the features of the actual embodiments and not to describe in detail the features and structures that are well known.

In general, terms may be understood at least partially from their use in context. For example, depending at least partially on the context, the term “one or more” as used herein may be used in a singular sense to describe any feature, structure, or characteristic, or may be used in a plural sense to describe a combination of features, structures, or characteristics. Similarly, terms such as “a” or “the” may also be understood to convey singular usage or to convey plural usage, which depends at least partially on the context. Furthermore, the term “based on” may be understood as not necessarily intended to convey an exclusive set of factors, and may alternatively allow for the presence of additional factors that are not necessarily explicitly described, which also depends at least partially on the context.

Unless otherwise defined, terms used herein are only intended to describe specific embodiments and are not limitations of the disclosure. As used herein, the singular forms such as “a” “one” and “the/that” are also intended to include the plural form unless the context clearly indicates otherwise. It should also be understood that the terms “comprising” and/or “including”, when used herein, determine the presence of the feature, integer, step, operation, element and/or component, but do not exclude the presence or addition of one or more other features, integers, steps, operations, elements, components and/or groups. When used herein, the term “and/or” includes any one and all combinations of the relevant listed items.

For a thorough understanding of the disclosure, detailed operations and detailed structures will be set forth in the following description in order to illustrate the technical solutions of the disclosure. Preferred embodiments of the disclosure are described in detail below, however, in addition to these detailed descriptions, the disclosure may have other implementation manners.

In some embodiments, the transistor of the memory includes a planar transistor (Planar) and a Buried Channel Array Transistor (BCAT). However, both the planar transistor and the buried channel transistor have a structure where the source and the drain are positioned on the horizontal two sides of the gate.

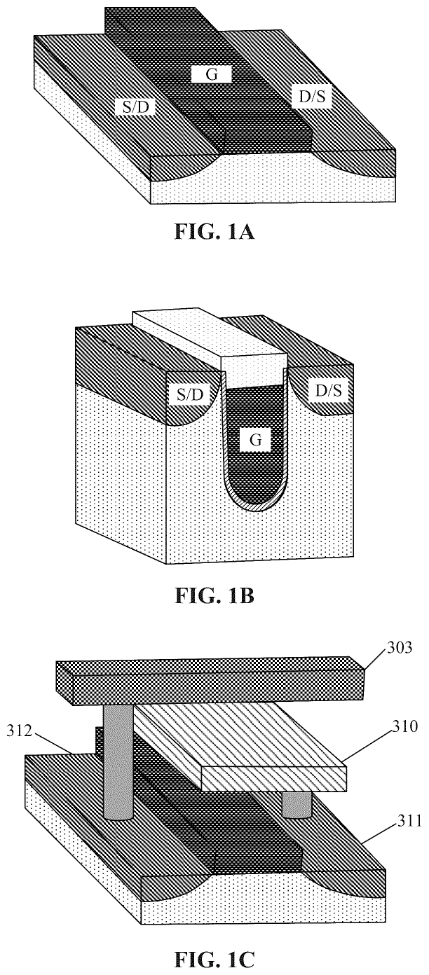

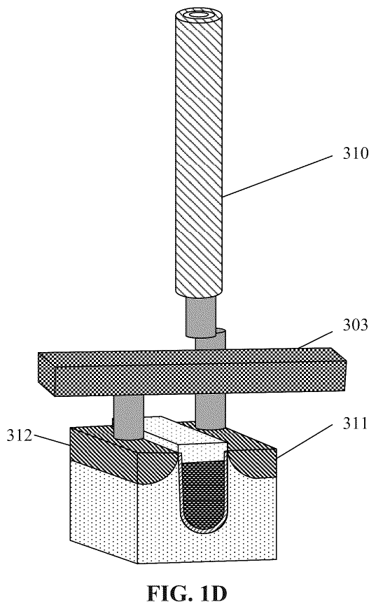

FIG. 1A is a structural schematic diagram of a planar transistor in some embodiments, and FIG. 1B is a structural schematic diagram of a buried channel transistor in some embodiments. As shown in FIGS. 1A and 1B, the source S and the drain D of the transistor are positioned on the horizontal two sides of the gate G. In this way, the source S and the drain D occupy different positions respectively in the horizontal plane, and thereby the horizontal area of either the planar transistor or the buried channel array transistor is relatively large.

Furthermore, since the transistor may be prepared on a silicon substrate, the transistor may be used in various memories, for example, a Dynamic Random Access Memory (DRAM). In general, a DRAM is composed of multiple storage arrays, and each storage array mainly includes a transistor and a capacitor manipulated by the transistor. That is, the DRAM includes the storage array including one transistor T and one capacitor C (1T1C).

FIG. 1C is a structural schematic diagram of a DRAM storage array formed by a planar transistor in some embodiments, and FIG. 1D is a structural schematic diagram of a DRAM storage array formed by a buried trench array transistor in some embodiments. As shown in FIGS. 1C and 1D, the source 312 (or drain 311) of the transistor in the DRAM storage array is connected to the bit line structure 303, and the drain 311 (or source 312) is connected to the capacitor 310.

Since the source and the drain of both of the planar transistor and the buried channel array transistor are positioned on the horizontal two sides of the gate respectively, the bit line and the capacitor in the DRAM storage array are also positioned on the same side of the gate. Furthermore, in the subsequent process, it is necessary to realize the connection among the bit line, the transistor and the capacitor, and the connection between the word line (WL) and the transistor, or the like. Therefore, the circuit wiring is complex and the manufacturing process is difficult in the storage array region of the DRAM memory.

The VCAT architecture has a higher storage density compared to the BCAT architecture. The source and the drain of the transistor in the VCAT architecture are positioned at the upper and lower ends of the vertical channel region. In the formation process of the semiconductor device, combined with wafer bonding and backside substrate thinning technologies, the bit line or other structures may be set up in two opposite sides of the wafer. For example, in case of a DRAM, the bit line and the capacitor of the DRAM storage array may be set up respectively on the two sides of the same wafer. In this way, the circuit layout of the word line, the bit line and the capacitor may be simplified and the difficulty of the manufacturing process of the semiconductor device may be reduced.

The process of the VCAT architecture is carried out on the backside of the thinned array wafer, and the bit line is required to be aligned with the lower end of the active region. In the case where the array wafer is affected by physical factors such as heat, local stress, overall warping, carrier wafer, bonding, or the like, there is a problem of overall warping and local stress, which affects the alignment between the bit line on the backside and the active region, thereby resulting in alignment failure.

In some embodiments, the self-aligned bit line structure may solve the problem of bit line alignment by etching backing the backside of the wafer such that the active region is etched at a deeper depth, and a long self-aligned bit line is formed in the etched region of the active region. However, there is a problem that the parasitic capacitance of the bit line is large.

Embodiments of the disclosure provide a method for manufacturing a semiconductor structure. The method includes the following operations as shown in FIG. 2.

In operation S101, a substrate is provided. The substrate has a first surface and a second surface that are opposite to each other.

In operation S102, a transistor array positioned in the substrate is formed from the first surface of the substrate. The transistor array includes multiple transistors, and a height of the transistor is less than a thickness of the substrate.

In operation S103, the substrate is thinned from the second surface until a first end of a conductive channel of the transistor is exposed. The first end is an end, which is close to the second surface, of the conductive channel.

In operation S104, an insulation layer covering at least a portion of the first end of the conductive channel is formed, such that a first width of an exposed portion of the first end of the conductive channel is less than a second width of the conductive channel.

In operation S105, a bit line structure covering the exposed portion of the first end of the conductive channel is formed.

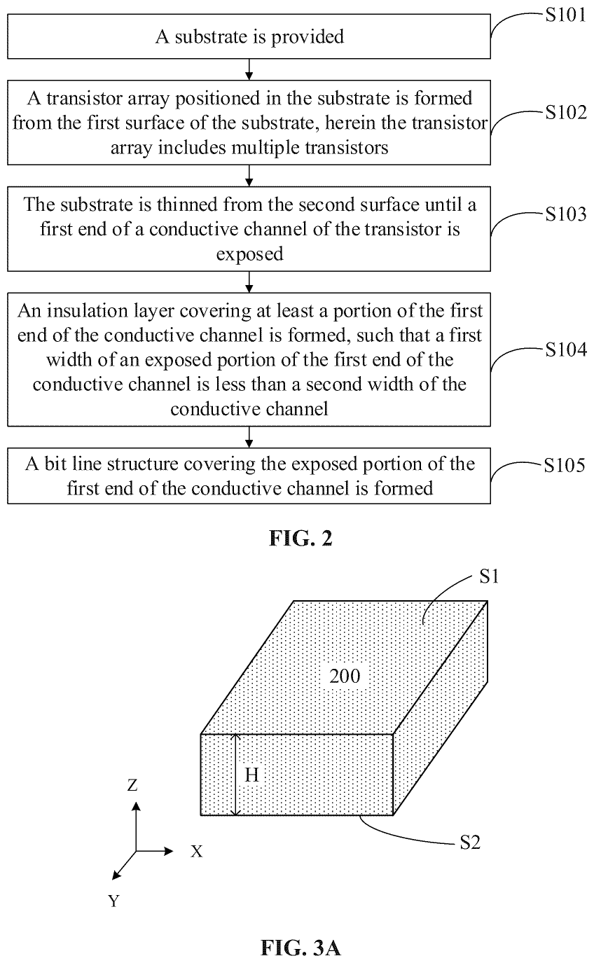

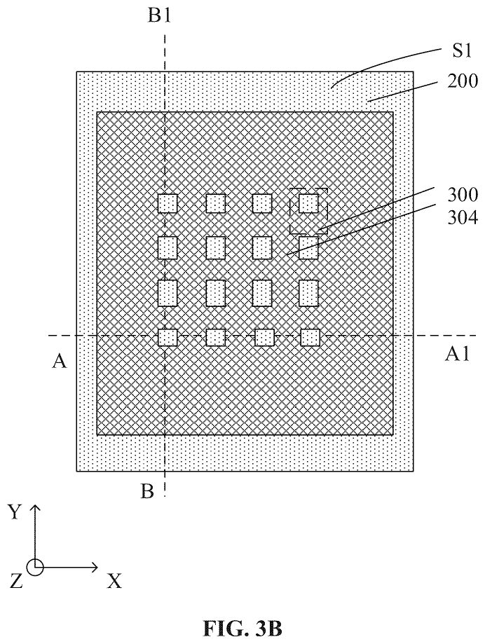

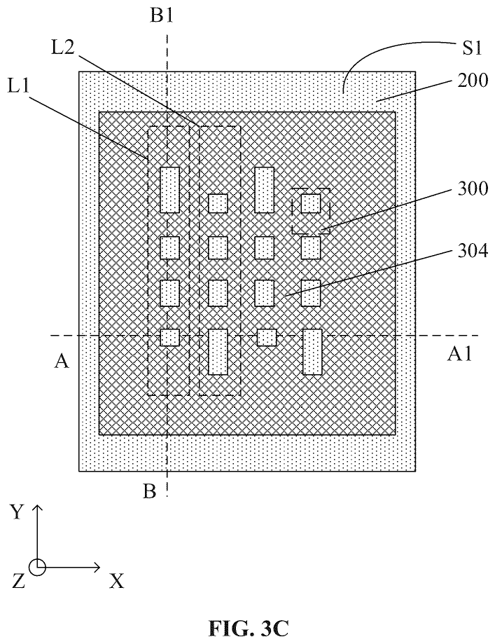

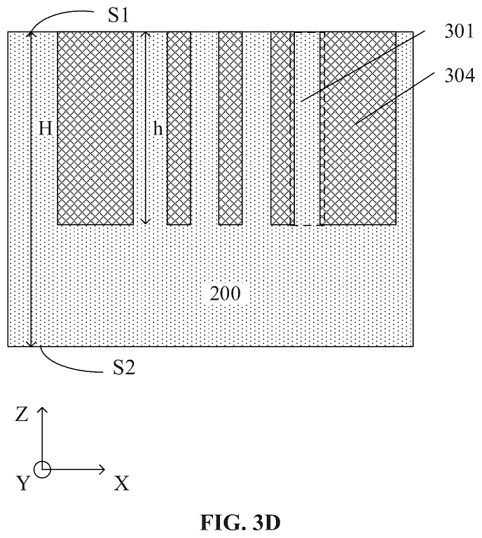

Firstly, the operation S101 is performed. The substrate 200 as shown in FIG. 3A is provided. The surface of the substrate 200 is any one of the surfaces perpendicular to the direction of the thickness of the substrate 200. The direction of the thickness of the substrate 200 or the direction perpendicular to the surface of the substrate 200 is defined as a Z direction, the thickness of the substrate 200 in the Z direction is defined as H, the top surface or the bottom surface of the substrate 200 perpendicular to the Z direction is defined as the first surface S1 and the second surface S2 that are opposite to each other, respectively, and an X direction and a Y direction, which are mutually intersecting, are defined in the first surface S1 or the second surface S2 perpendicular to the Z direction. In some embodiments, the X direction is the direction in which the transistor forms a gate, and the Y direction is the direction in which the transistor forms a bit line. The semiconductor substrate 200 may include a P-type semiconductor material substrate (such as a silicon (Si) substrate or a germanium (Ge) substrate, or the like), an N-type semiconductor substrate (such as an indium phosphide (InP) substrate), a composite semiconductor material substrate (such as a silicon-germanium (SiGe) substrate, a silicon-on-insulator (SOI) substrate, a germanium-on-insulator (GeOI) substrate, or the like). Furthermore, the substrate in the embodiments of the disclosure may also be a substrate that has been formed with a portion of a device structure or has some wiring, which is not limited herein.

The operation S102 is performed. A transistor array positioned in the substrate 200 is formed by processing the substrate 200 by processes such as etching and deposition from the first surface S1 of the substrate 200. FIG. 3B is a top view of the transistor array positioned in the substrate in the direction from S1 toward S2. The transistor array may have N rows in the X direction, and the transistor array may have M columns in the Y direction, here, N and M are positive integers greater than or equal to 1. The transistor array in FIG. 3B is arranged as rows being aligned with rows and columns being aligned with columns. FIG. 3C shows another arrangement of the transistor array. The columns of transistors in the transistor array in FIG. 3C are arranged as staggered up and down, for example, column 1L1 is in an above position relative to column 2L2. The arrangement of the transistor array is not limited to the above, and there may be a variety of arrangements. The transistor array includes multiple transistors 300, and each transistor is used to perform a storage function of data.

FIG. 3D is a sectional view of FIG. 3B or FIG. 3C at AA1. As shown in FIG. 3D, the transistor in the substrate 200 has a certain height h, and the height h of the transistor is less than the thickness H of the substrate. That is, the transistor is formed between the first surface S1 and the second surface S2, and the transistor has a certain distance (H-h) from the second surface S2 of the substrate.

The operation S103 is performed. The substrate is turned over, and the substrate 200 is then thinned from the second surface S2 until the first end of the conductive channel 301 of the transistor 300 is exposed, as shown in FIG. 5A. FIG. 5A is a top view of the thinned substrate in the direction of the second surface S2, and the method for thinning include, but is not limited to, an etching process and Chemical Mechanical Polishing (CMP). FIG. 5B is a sectional view of FIG. 5A at AA1. In the direction from the second surface S2 towards the first surface S1, the exposed first end D1 of the conductive channel 301 is recessed with respect to the second surface S2 of the thinned substrate, and an opening above the conductive channel 301 in such case has a second width a. Here, the first end D1 is an end, which is close to the second surface S2, of the conductive channel 301.

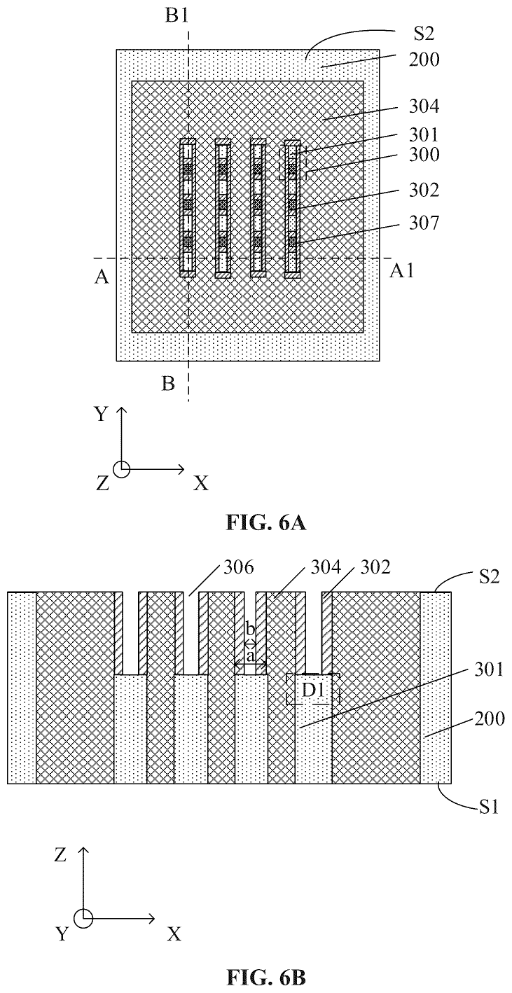

The operation S104 is performed. An insulation layer 302 covering at least a portion of the first end of the conductive channel is then formed, such that the second width a of the exposed portion above the first end of the conductive channel 301 is reduced. FIG. 6A is a top view of the substrate in the direction of the second surface S2, and FIG. 6B is a sectional view of FIG. 6A at AA1. It can be understood that the opening of the conductive channel 301 after the insulating layer 302 is filled has a first width b, which is less than the second width a of the opening above the conductive channel 301 before the insulating layer 302 is filled, that is, the first width b of the exposed portion of the first end of the conductive channel 301 is less than the second width a of the conductive channel.

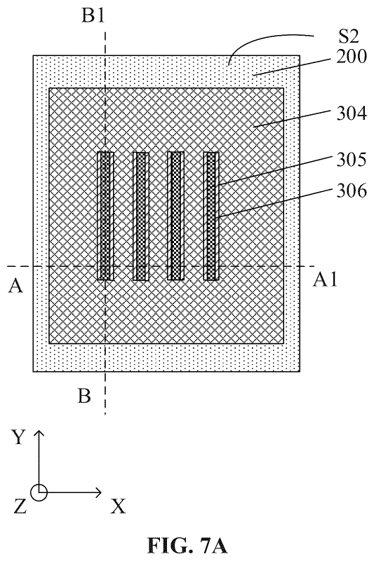

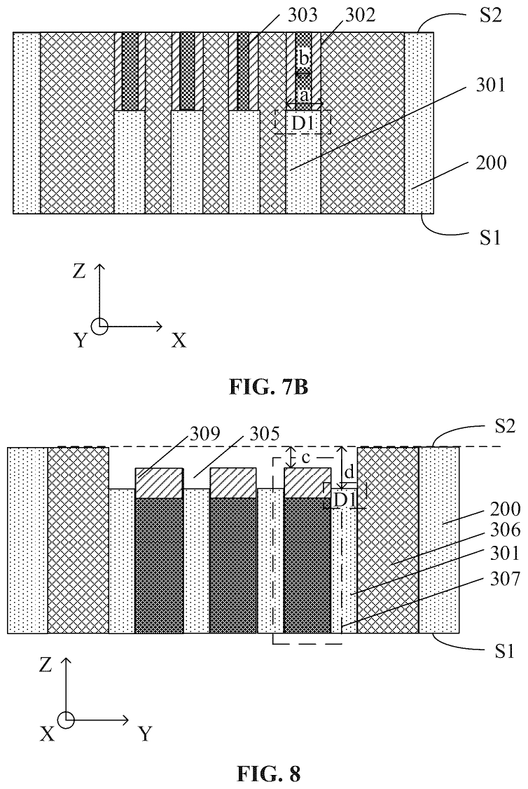

The operation S105 is performed. A bit line structure 303 covering the exposed portion of the first end of the conductive channel is finally formed at the opening of the conductive channel after the insulation layer is filled. FIG. 7A is a top view of the substrate with the bit line structure 303 formed in the direction of the second surface S2. FIG. 7B is a sectional view of FIG. 7A at AA1. The bit line structure 303 is formed above the conductive channel 301. Method for forming the bit line structures 303 includes, but is not limited to, a growth process and a deposition process. The conductive material used to form the bit line structures 303 includes, but is not limited to, tungsten, cobalt, copper, aluminum, polycrystalline silicon (including doped polycrystalline silicon), doped silicon, metal silicide (such as titanium silicide), or any combination thereof. The bit line structure may use one or more of the above conductive materials, and thus the bit line structure may be monolayer or multilayer.

According to the embodiments of the disclosure, the size of the bit line channel is reduced by a sidewall deposition/etching process after etching backing of the backside substrate, thereby reducing the key size of the bit line, reducing the parasitic capacitance between the bit lines, and improving the reading performance of the transistor. Furthermore, the bit line structure in the embodiments of the disclosure is formed directly on the bit line structure, which will not result in alignment failure due to the overall warping and local stress of the substrate. The probability of alignment failure between the bit line and the source is reduced.

In some embodiments, as shown in FIG. 3B, a dielectric layer 304 is filled between the multiple transistors. In the above operation S104, the operation of forming the insulation layer 302 covering at least the portion of the first end of the conductive channel includes the following operations.

In operation S201, after the substrate 200 is thinned, a portion of the conductive channel 301 is continued to be etched from the first end of the conductive channel 301, to form multiple recessed structures 305 between the dielectric layers 304.

In operation S202, the insulation layer 302 is formed on a sidewall of the recessed structure 305, such that the insulation layer 302 covers at least the portion of the first end D1 of the conductive channel to form a trench 306 with a sidewall covered by the insulation layer 302.

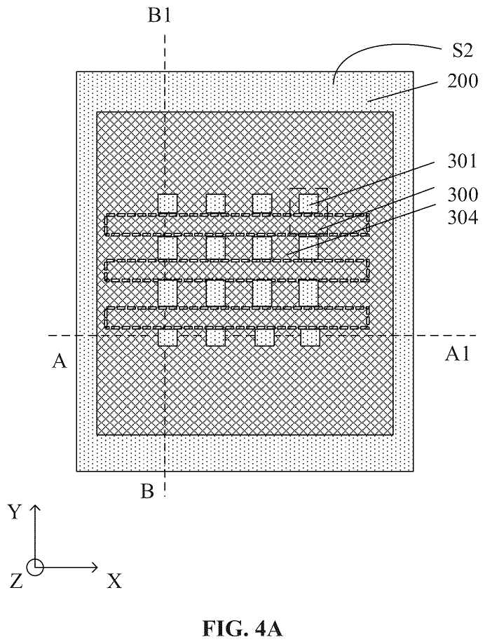

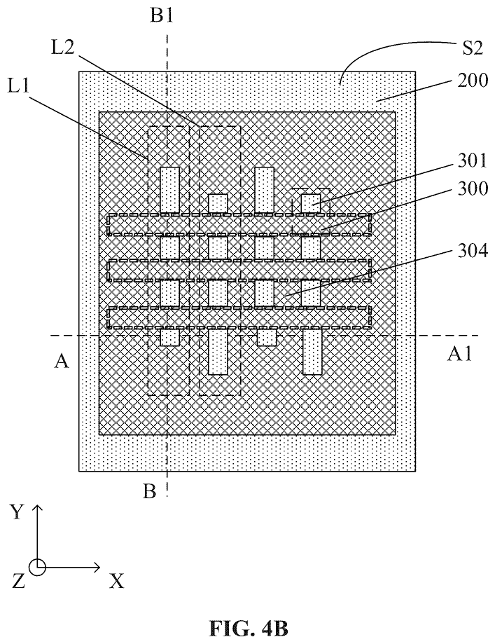

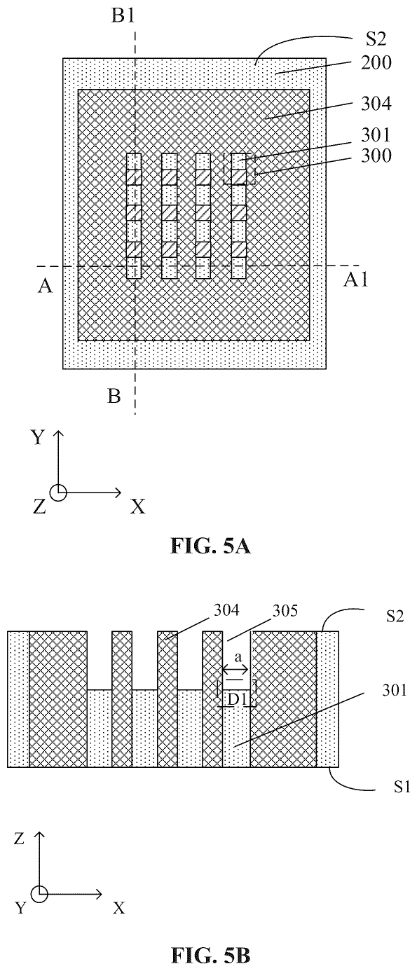

In the operation S201, the transistor array composed of multiple transistors is further filled with the dielectric layer 304, and the dielectric layer 304 may be silicon dioxide or other insulating material. The dielectric layer 304 is used for electrical isolation between the transistors. The substrate 200 is thinned from the second surface S2. As shown in FIGS. 4A and 4B, thinning is stopped at the point when the first end of the conductive channel of the transistor is just exposed, and the first end of the conductive channel of the transistor is continued to be etched. The etching process includes, but is not limited to, dry etching and wet etching. As shown in FIG. 5B, the recessed structure 305 positioned on the first end D1 of the conductive channel 301 is formed between two adjacent dielectric layers 304, and multiple recessed structures 305 are formed on multiple transistor arrays. The multiple recessed structures 305 may be connected.

The recessed structure 305 has two opposite sidewalls. As shown in FIG. 6B, the insulation layer 302 is formed on the sidewall. The insulation layer 302 may be formed by a growth process, for example, In-Situ Steam Generation (ISSG) in a selective growth manner. The In-Situ Steam Generation is a thermal annealing deposition method which forms a high quality oxide film by heating in a cavity and passing oxygen atoms to combine with atoms in the semiconductor substrate. A deposition process may also be used, which may include CVD, Physical Vapor Deposition (PVD), Plasma Enhanced Chemical Vapor Deposition (PECVD), Sputtering, Metal Organic Chemical Vapor Deposition (MOCVD), Atomic Layer Deposition (ALD), or the like. The formed insulation layer 302 covers the sidewall of the recessed structure 305 and covers at least a portion of the first end D1 of the conductive channel to form the trench 306 with the sidewall covered by the insulation layer 302. It can be understood that the opening of the trench 306 is less than the opening of the recessed structure 305. The insulation layer 302 may be silicon dioxide or other insulating material, and the material of the insulation layer 302 may be the same as or different from that of the dielectric layer 304.

In some embodiments, in the above operation S202, the operation of the operation of forming the insulation layer 302 on the sidewall of the recessed structure 305 includes the following operations.

In operation S301, a bottom surface and the sidewall of the recessed structure 305 are covered by an insulation material.

In operation S302, the insulation material covering the bottom surface of the recessed structure 305 is removed to form the insulation layer 302 covering the sidewall of the recessed structure.

In some embodiments, the formation of the insulation layer 302 on the sidewall of the recessed structure 305 is a one-step formation. For example, the insulation layer 302 covering the sidewall of the recessed structure is formed by performing a method including, but not limited to, a growth process and a deposition process only on the sidewall of the recessed structure 305.

In some embodiments, the formation of the insulation layer 302 on the sidewall of the recessed structure 305 is performed in multiple operations, for example, by two operations. In the operation 301, the insulation layer 302 may be formed on the sidewall and bottom surface (that is, the surface of the first end of the conductive channel) of the recessed structure 305 by a growth process or a deposition process. In the operation 302, the insulation layer 302 covering the bottom surface of the recessed structure 305 is removed by a method including, but not limited to, wet etching or dry etching (for example, a plasma etching process or a reactive ion etching process). Compared to the material of the first end D1 of the conductive channel, the material used to form the insulation layer 302 may have a high etch selectivity ratio, and thereby the first end D1 of the conductive channel is taken as an etching stop layer.

The etching method may use an anisotropic etching process, such that the rate of lateral etching is far less than the rate of longitudinal etching, thereby allowing the lateral insulation layer 302 to be retained.

In some embodiments, FIG. 8 is a sectional view of FIG. 5A at BB1. As shown in FIG. 8, there is a word line structure 307 of the transistor between two adjacent conductive channels 301, the word line structure 307 is positioned in a region of the recessed structure 305, and the depth of the recessed structure 305 positioned on the word line structure 307 is less than the depth of the recessed structure 305 positioned on the conductive channel 301.

In the above operation S202, the operation of forming, in the recessed structure 305, the insulation layer covering at least the portion of the first end of the conductive channel 301 further includes the following operation.

In operation S401, the insulation layer covering a portion of the word line structure 307 and covering at least the portion of the first end of the conductive channel 301 is formed in the recessed structure 305.

In some embodiments, there is the word line structure 307 of the transistor between two adjacent conductive channels 301. The two conductive channels 301 may share a word line structure 307 to form a transistor, or one of the conductive channels 301 may use a word line structure 307 to form a transistor. When a portion of the conductive channel 301 is etched from the first end D1 of the conductive channel, a portion of the substrate above the word line structure 307 is also etched, and the recessed structure 305 further includes a region positioned above the word line structure 307.

In some embodiments, the word line structure 307 is formed between two conductive channels 301, the word line structure 307 has an isolation layer 309, and the isolation layer 309 is used to isolate the gate and the drain (or the source). Before the substrate is thinned to expose the first end D1 of the conductive channel 301, there is still the substrate on the isolation layer 309, that is, the depth of the word line structure 307 formed in the substrate is less than the depth of the conductive channel 301 in the substrate. In the case where the region where the conductive channel 301 and the word line structure 307 are positioned is etched downwardly, after the substrate on the word line structure 307 has been etched completely, the isolation layer 309 is taken as the etching stop layer. However, there is no etching stop layer on the first end D1 of the conductive channel 301, and thus the etched depth of the first end of the conductive channel 301 is deeper than the etched depth of the word line structure 307. The etched region on the first end of the conductive channel 301 and the etched region on the word line structure 307 form the recessed structure 305 (recessed downwardly with respect to the substrate on both sides of the transistor array) together, and thus the depth of the recessed structure 305 positioned on the word line structure 307 is less than the depth of the recessed structure 305 positioned on the conductive channel 301.

In some embodiments, in the case where the insulation layer is formed on the sidewall of the recessed structure 305, the insulation layer covering a portion of the word line structure 307 is further formed above the word line structure 307. The method of forming the insulation layer covering a portion of the word line structure 307 above the word line structure 307 and the method of forming the insulation layer covering at least a portion of the first end of the conductive channel 301 on the sidewall of the recessed structure 305 may be the same or different. The insulation layer covering a portion of the word line structure 307 and the insulation layer covering the first end of the conductive channel 301 may be formed simultaneously or in stages.

In some embodiments, in the above operation S105, the operation of forming the bit line structure 303 covering the exposed portion of the first end of the conductive channel 301 includes the following operation.

In operation S501, a conductive material is deposited in the trench 306 to form the bit line structure 303. The width of the trench 306 is equal to the first width.

The recessed structure 305 becomes the trench 306 after the sidewall is covered by the insulation layer 302. The trench 306 may be covered by a conductive material by a growth process or a deposition process. The bit line structure 303 may be formed by one or more conductive materials. For example, in some embodiments, one conductive material may be used to fill the trench 306 until it is flush with the first end of the conductive channel 301. Furthermore, in some embodiments, three conductive materials may be used to fill the trench 306 in stages until it is flush with the first end of the conductive channel 301. The width of the opening of the trench 306 is the first width of the exposed first end of the conductive channel 301. The conductive material includes, but is not limited to, tungsten, cobalt, copper, aluminum, polycrystalline silicon, doped silicon, silicide, or any combination thereof. Therefore, the bit line structure 303 may include a single membrane layer (using one conductive material) or may also include multiple membrane layers (using multiple conductive materials), which is not limited herein.

In some embodiments, the method further includes the following operations.

In operation S601, a carrier wafer is provided.

In operation S602, the first surface S1 of the substrate and the carrier wafer are bonded.

In some embodiments, before the second surface S2 of the substrate is thinned, it is necessary to fix the first surface S1 of the substrate on a support structure to prevent damaging the structure of the formed transistor array when the second surface S2 of the substrate is thinned. The support structure may be a carrier wafer, and the carrier wafer may use the same material as the substrate. For example, in the case where the substrate is a silicon substrate, the wafer may be a silicon wafer. The first surface S1 of the substrate and the surface of the carrier wafer are then bonded together.

In some embodiments, in the above operation S103, the operation of thinning the substrate from the second surface until the first end of the conductive channel of the transistor is exposed includes the following operations.

In operation S701, the carrier wafer and the substrate are flipped, such that the second surface is vertically upward.

In operation S702, the substrate is thinned from the second surface until the first end of the conductive channel of the transistor is exposed.

In some embodiments, when the substrate is thinned from the second surface S2, the carrier wafer and the first surface S1 of the substrate have already been bonded. It is necessary to flip the carrier wafer and the substrate before thinning, such that the second surface S2 is vertically facing up and the surface on which the carrier wafer is positioned is facing down. The substrate is then thinned from the second surface and the thinning of the substrate may be stopped when the first end of the conductive channel 301 of the transistor is exposed.

In some embodiments, the method further includes the following operation.

In operation S801, a storage capacitor connected to the transistor is formed on the first surface S1 of the substrate 200.

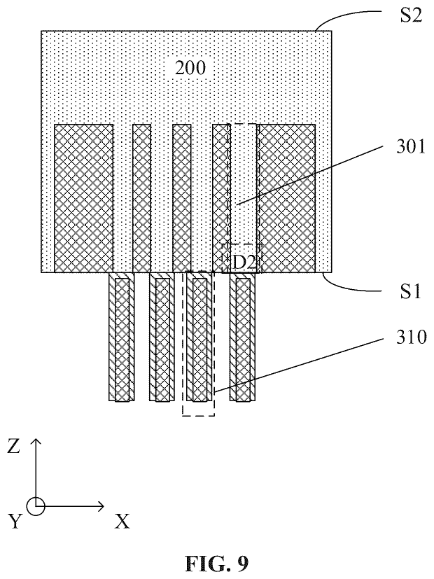

As shown in FIG. 9, the storage capacitor 310 may further be formed on the first surface S1 of the substrate 200 and on a second end D2 corresponding to the first end of the conductive channel 301. The storage capacitor 310 is used for storing data written into the memory cell. There may further be a dielectric layer between the storage capacitors 310 for electrical isolation from each other.

In some embodiments, the method further includes the following operations: In operation S901, a drain is formed at the first end of the conductive channel.

In operation S902, a source is formed at a second end of the conductive channel. The second end is an end, which is close to the first surface, of the conductive channel.

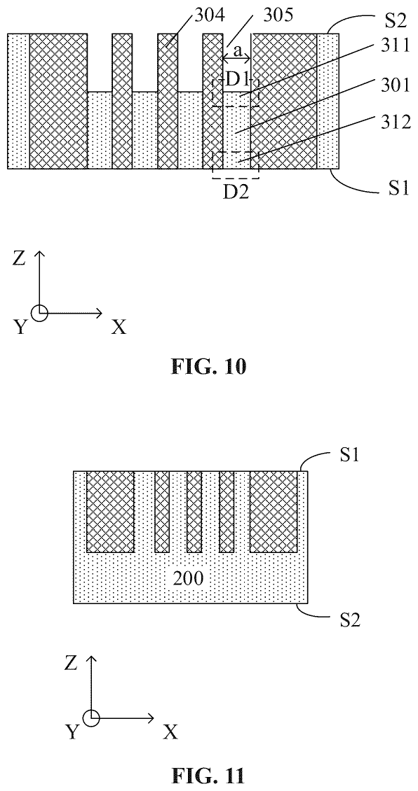

As shown in FIG. 10, in some embodiments, the drain 311 is formed at the first end D1 of the conductive channel 301 by processes including, but not limited to, ion implantation and thermal diffusion. The ion implantation and thermal diffusion may be performed after the first end of the conductive channel is exposed, or before the bit line structure is formed.

The source 312 is formed at the second end D2 of the conductive channel 301. The second end is an end, which is close to the first surface S1, of the conductive channel 301. The source may also be formed at the first end D1 of the conductive channel 301 by processes including, but not limited to, ion implantation and thermal diffusion. The second end D2 of the conductive channel 301 is exposed until the storage capacitor 310 is formed, and thus the source may be formed before the storage capacitor 310 is formed.

In some embodiments, the positions of the source 312 and the drain 311 may be interchanged. That is, the source 312 is formed at the first end D1 of the conductive channel 301, and the drain 311 is formed at the second end D2 of the conductive channel 301. Here, the second end D2 is an end, which is close to the first surface S1, of the conductive channel 301.

Embodiments of the disclosure further provide a semiconductor structure. As shown in FIG. 7B, the semiconductor structure includes a substrate 200, a transistor array, an insulation layer 302, and a bit line structure 303.

The substrate 200 has a first surface S1 and a second surface S2 that are opposite to each other.

The transistor array is positioned in the substrate 200. The transistor array includes multiple transistors.

The insulation layer 302 covers at least a portion of a first end D1 of a conductive channel 301, such that a first width b of a portion of the first end D1 of the conductive channel 301, which is not covered by the insulation layer 302, is less than a second width a of the conductive channel 301. The first end D1 is an end, which is close to the second surface S2, of the conductive channel 301.

The bit line structure 303 is connected to the portion of the first end D1 of the conductive channel 301, which is not covered by the insulation layer 302.

The semiconductor substrate 200 has a certain thickness, and thereby has the first surface S1 and the second surface S2 that are opposite to each other. The semiconductor substrate 200 may have an array composed of transistors thereon for realizing functions, such as data storage, as well as data read and write. The transistor includes at least one conductive channel 301.

The first end D1 of the conductive channel 301 is an end, which is close to the second surface S2, of the conductive channel, and is partially covered by the insulation layer 302. The bit line structure 303 is positioned between the opposite insulation layers on the conductive channel 301 and covers the portion of the first end of the conductive channel that is not covered by the insulation layer.

According to the embodiments of the disclosure, the size of the bit line channel is reduced by a sidewall deposition/etching process after etching backing of the backside substrate, thereby reducing the key size of the bit line, reducing the parasitic capacitance between the bit lines, and improving the reading performance of the transistor. Furthermore, the bit line structure in the embodiments of the disclosure is formed directly on the bit line structure, which will not result in alignment failure due to the overall warping and local stress of the substrate. The probability of alignment failure between the bit line and the source is reduced.

In some embodiments, as shown in FIG. 5B, the semiconductor structure further includes a dielectric layer 304.

The dielectric layer 304 are positioned between the multiple transistors.

The dielectric layer 304 are positioned between the multiple transistors, and are used for electrical isolation between the transistors. That is, the dielectric layer 304 is between the transistors. One transistor may be electrically isolated from another transistor by such a dielectric layer 304.

The dielectric layer 304 may be formed by depositing a silicon nitride layer on the semiconductor substrate and then patterning the silicon nitride layer to form a hard mask. The semiconductor substrate is then etched to form recesses between adjacent transistor elements. Finally, the recesses are filled with oxides to form the dielectric layer described above. In the embodiments of the disclosure, the depth of the dielectric layer may be greater than or equal to the depth of the transistor, and thereby the effect of electrical isolation is better.

Multiple recessed structures 305 are positioned between the dielectric layers 304.

Before the bit line structures 303 as shown in FIG. 7B is formed, the multiple recessed structures 305 are positioned between the dielectric layers 304, and the conductive channel 301 is between the dielectric layers. The recessed structure 305 is above each conductive channel 301, and the recessed structure 305 is used for the subsequent placement of the bit line structure. In some embodiments, the bit line structure penetrates in the BB1 direction, and thus the recessed structure 305 penetrates in the BB1 direction of FIG. 5A.

In some embodiments, as shown in FIG. 6B, the insulation layer 302 is positioned on a sidewall of the recessed structure, the insulation layer 302 covers at least the portion of the first end D1 of the conductive channel 301, and the recessed structure with the sidewall covered by the insulation layer 302 is a trench 306.

The insulation layer 302 covers at least a portion of the first end D1 of the conductive channel 301, and the insulation layer 302 also covers the sidewall of the recessed structure. The part above the first end D1 of the conductive channel 301 is the recessed structure in the case where the part is not covered by the insulation layer 302, and the part above the first end D1 of the conductive channel 301 is the trench 306 in the case where the part is covered by the insulation layer 302, that is, in the case where the sidewall is covered by the insulation layer. It can be understood that the width b of the trench is less than the width a of the recessed structure. The insulation layer 302 may cover the two opposite sidewalls of the recessed structure, or cover any one of the two opposite sidewalls, by both of which the dimension of the trench 306 formed after being covered may be reduced relative to the dimension of the recessed structure 305, that is, the dimension of the subsequently formed bit line structure is reduced.

In some embodiments, as shown in FIG. 7B, the bit line structure 303 is positioned in the trench, and the width of the trench may be equal to the first width.

The bit line structure 303 is positioned in the trench and fills the trench. Thus, the width of the trench is the first width a, and the width of the bit line structure 303 is also the first width a. The material forming the bit line structure may be a conductive material including, but not limited to, tungsten (W), cobalt (Co), copper (Cu), aluminum (Al), polycrystalline silicon, doped silicon, metal silicide (such as titanium silicide), or any combination thereof.

FIG. 8 is a sectional view of FIG. 5A at BB1. In some embodiments, as shown in FIG. 8, the semiconductor structure further includes a word line structure 307 of the transistor.

The word line structure 307 is positioned between two adjacent conductive channels 301, the word line structure 307 is positioned in a region of the recessed structure 305, and the depth c of the recessed structure 305 positioned on the word line structure 307 is less than the depth d of the recessed structure 305 positioned on the conductive channel 301.

In some embodiments, the word line structure 307 of the transistor is positioned between two conductive channels 301, the gate of the transistor is formed in the word line structure 307, and the word line structure 307 includes the gate extending in the Y direction. In the transistor array, the gates in the same row may be connected, and the transistors in the same row may share the same gate. The gates in the same row may also be disconnected, and each transistor is connected to a respective gate. The recessed structure 305 penetrates in the Y direction, and thus the recessed structure 305 may also be formed above the word line structure 307.

In some embodiments, since the end of the word line structure 307 which is close to the second surface S2 has an isolation layer, in the case where the substrate is etched downwardly in the direction of the second surface S2 to the isolation layer, the isolation layer may be taken as an etching stop layer. However, there is no etching stop layer on the conductive channel, and thus the etched depth d of the conductive channel is greater than the etched depth c of the word line structure. That is, the depth of the recessed structure 305 positioned on the word line structure 307 may be less than the depth of the recessed structure 305 positioned on the conductive channel 301.

In other embodiments, it is possible not to form the recessed structure 305 on the word line structure 307, and only form the bit line structure 303 on the conductive channel 301. The bit line structure 303 formed on each conductive channel 301 is then bridged on the word line structure 307.

In some embodiments, as shown in FIG. 6A, the insulation layer 302 further covers a portion of the sidewall of the word line structure 307. This is because in some embodiments, the depth on the word line structure 307 is less than the depth of the recessed structure 305 on the conductive channel 301, that is, the top of the word line structure 307 is higher than the top of the conductive channel 301, and thus the deposited insulation layer may further partially cover the sidewall of the word line structure 307.

In some embodiments, the insulation layer 302 further covers a portion of the word line structure 307, such that the width of the opening of the recessed structure 305 above the word line structure 307 is also reduced. The width of the insulation layer 302 covering the word line structure 307 and the width of the insulation layer 302 covering the first end of the conductive channel 301 may be the same or different.

In some embodiments, as shown in FIG. 9, the semiconductor structure further includes a storage capacitor 310.

The storage capacitor 310 is positioned on the first surface S1 of the substrate and connected to the transistor.

In some embodiments, in the case where the semiconductor device is a DRAM, the memory cell further includes a storage capacitor 310. FIG. 9 is a structural schematic diagram of a DRAM memory cell provided by embodiments of the disclosure. As shown in FIG. 9, it can be seen that in the DRAM storage array, an end of the storage capacitor 310 is connected to the first end of the conductive channel 301 to form a memory cell of the 1T1C architecture. In the memory cell, the storage capacitor 310 is connected to the second end D2 of the conductive channel 301 of the transistor for storing data written into the memory cell.

In some embodiments, as shown in FIG. 10, the first end of the conductive channel includes the drain of the transistor.

The second end D2 of the conductive channel 301 includes the source of the transistor 312, and the second end is an end, which is close to the first surface S1, of the conductive channel.

The first end of the conductive channel 301 is the drain 311 of the transistor, which is close to the second surface S2. The second end of the conductive channel, that is, the end, which is close to the first surface S1, of the conductive channel 301, is the source 312 of the transistor. The channel is between the drain 311 and the source 312 of the transistor.

In some embodiments, the positions of the source 312 and the drain 311 may be interchanged. That is, the source 312 is the first end D1 of the conductive channel 301, and the drain 311 is the second end D2 of the conductive channel 301. Here, the second end D2 is an end, which is close to the first surface S1, of the conductive channel 301.

The source 312 and the drain 311 are not required to be on the same surface of the substrate, which may further reduce the area on the surface of the substrate, which is occupied by each transistor and the storage unit on which each transistor is positioned, and greatly increase the number of storage units that may be arranged on the substrate as well as the utilization rate of the substrate. The drain of the transistor is connected to the bit line structure for performing a read or write operation on the memory cell on which the transistor is positioned when the transistor is on.

Embodiments of the disclosure further provide the following examples.

In some embodiments, the bit line of the transistor may be formed by the following operations.

As shown in FIG. 11, a substrate 200 with a to-be-formed bit line is provided, and the substrate 200 has a first surface S1 and a second surface S2 that are opposite to each other. A transistor array is in the substrate, and the transistor array includes at least one transistor. In some embodiments, the transistor array may further be connected to a storage capacitor, where one transistor may be connected to one storage capacitor. The surface to which the storage capacitor is close is the second surface S2. The storage capacitor and the bit line are positioned on opposite surfaces, that is, the bit line is formed on the first surface S1 of the substrate.

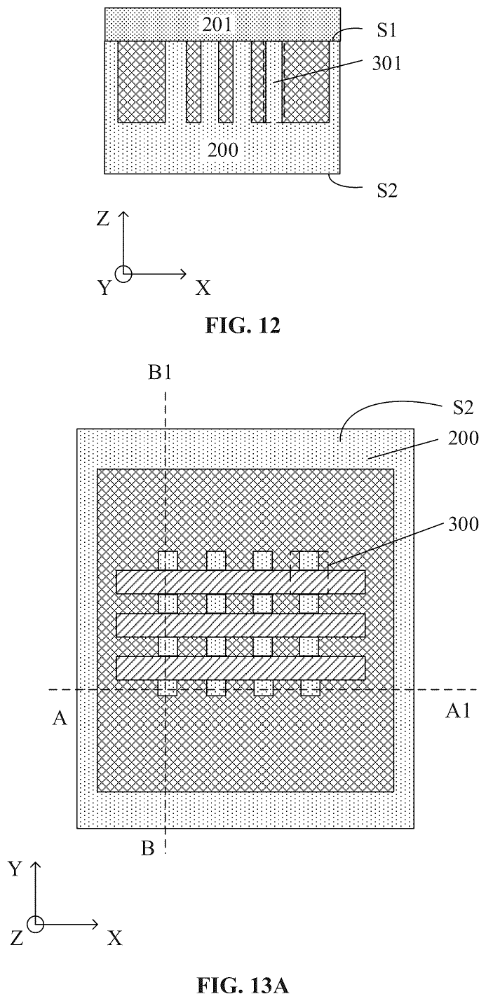

As shown in FIG. 12, a carrier wafer 201 is provided. The first surface S1 of the substrate 200 with the to-be-formed bit line and the carrier wafer 201 are bonded. After that, the carrier wafer 201 and the substrate 200 are flipped, such that the second surface S2 is vertically upward.

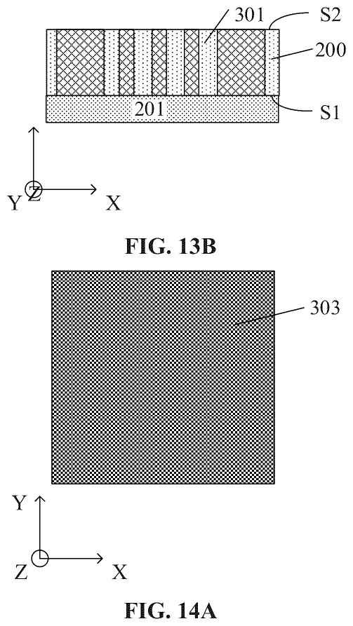

The substrate is thinned along the second surface S2 as shown in FIG. 13A and FIG. 13B. FIG. 13A is a top view of the thinned substrate along the surface S2, and FIG. 13B is a sectional view of FIG. 13A in the X direction. The method for thinning includes, but is not limited to, dry etching, wet etching, CMP, or the like, until the first end of the conductive channel 301 of the transistor close to the surface S2 in the substrate 200 is exposed.

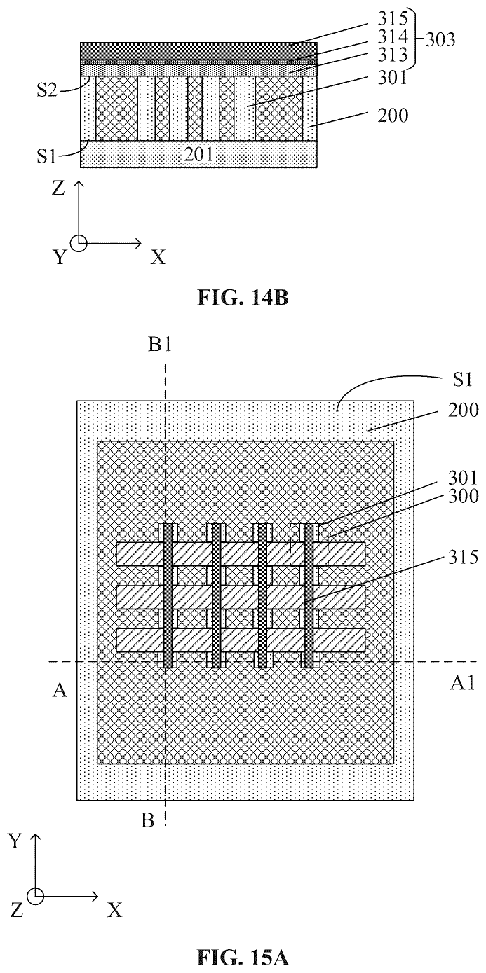

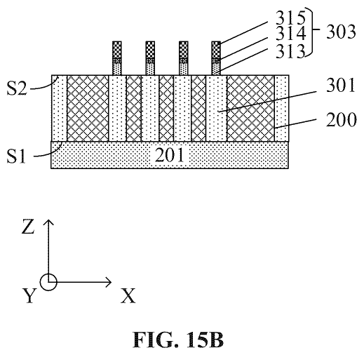

FIG. 14A is a top view along the surface S2 after the bit line material is deposited, and FIG. 14B is a sectional view of FIG. 14A in the X direction. As shown in FIG. 14A and FIG. 14B, the method for depositing the bit line structure includes the following operations. A doped polysilicon layer 313, a metal silicide layer 314 (for example, titanium silicide), and a metal layer 315 (for example, tungsten) are sequentially deposited on the second surface S2 of the transistor array. A semiconductor structure as shown in FIGS. 15A and 15B is then formed by Self-aligned Double Patterning (SADP). FIG. 15A is a top view of the formed bit line structure along the surface S2, and FIG. 15B is a sectional view of FIG. 15A in the AA1 direction. A bit line structure 303 is positioned above the first end of the conductive channel 301, and the bit line structure 303 is composed of the polysilicon layer 313, the metal silicide layer 314 (for example, titanium silicide), and the metal layer 315 (for example, tungsten).

The bit line formed by the above method is required to be aligned with the lower end of the active region. Due to the effect of physical factors such as heat, local stress, overall warping, carrier wafer, bonding, or the like, there is a problem of overall warping and local stress, which affects the alignment between the bit line on the backside and the active region, thereby easily resulting in alignment failure of the bit line.

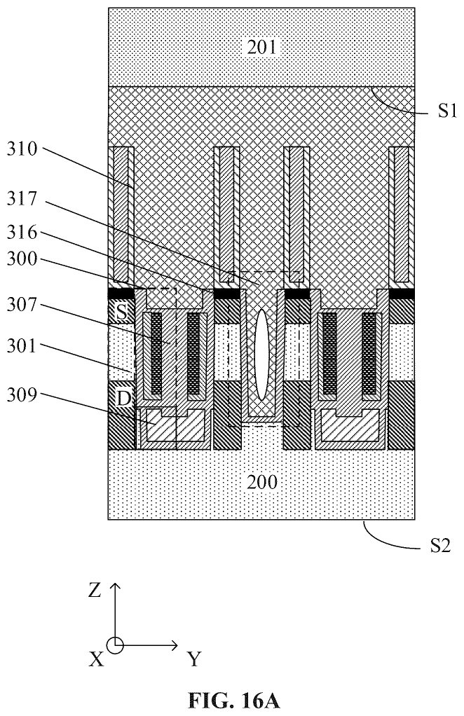

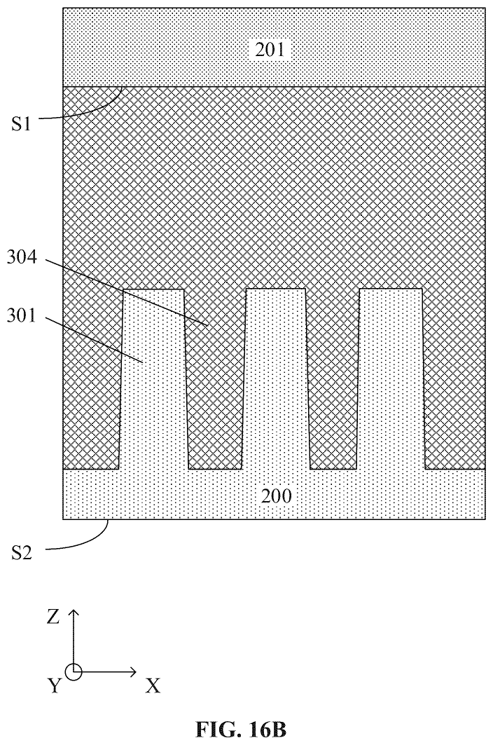

FIG. 16A is a sectional view of the semiconductor structure in the direction of the to-be-formed bit line. In some embodiments, as shown in FIG. 16A, a substrate 200 with the to-be-formed bit line is provided. The substrate has a first surface S1 and a second surface S2 that are opposite to each other, and a transistor array is formed in the substrate 200. The transistor array is composed of multiple transistors 300, and a transistor 300 is connected to a storage capacitor 310 through a conductive plug 316. The material of the conductive plug 316 may be a metal silicide, and the conductive plug 316 is used to form an ohmic contact between the storage capacitor 310 and the transistor 300. In some embodiments, it is also possible to directly connect the transistor 300 to the storage capacitor 310 without the conductive plug 316. The storage capacitor 310 is close to the first surface S1, and the storage capacitor 310 and the to-be-formed bit line are positioned on opposite surfaces respectively, that is, the bit line will be formed on the second surface S2 of the substrate. Two transistors 300 opposite to each other are set as a group of transistors. The word line structures 307 in a group of transistors are adjacent to each other, and the conductive channels 301 in a group of transistors are not adjacent to each other. The word line structure 307 has an isolation layer 309 at the end close to the second surface of the substrate 200. There may further be an air trench 317 between one group of transistors and another group of transistors.

FIG. 16B is a sectional view of the semiconductor structure in the direction in parallel with the word line structure. As shown in FIG. 16B, there is further a dielectric layer 304 between the conductive channels 301, and the conductive channel 301 further has a certain thickness from the second surface S2 of the substrate 200.

A carrier wafer 201 is provided. The first surface S1 of the substrate with the to-be-formed bit line and the carrier wafer 201 are bonded. After that, the carrier wafer and the substrate are flipped, such that the second surface S2 is vertically upward.

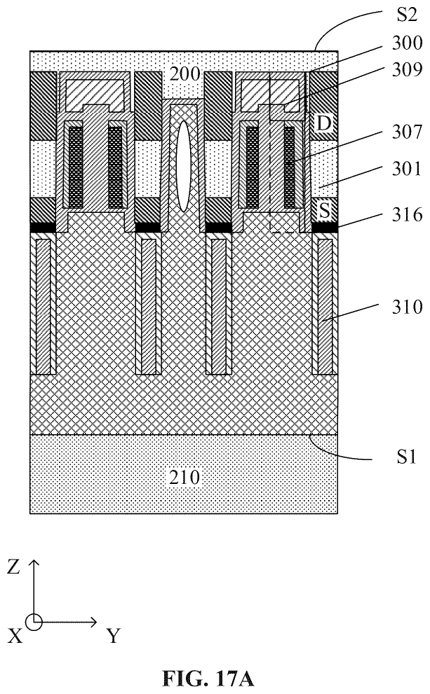

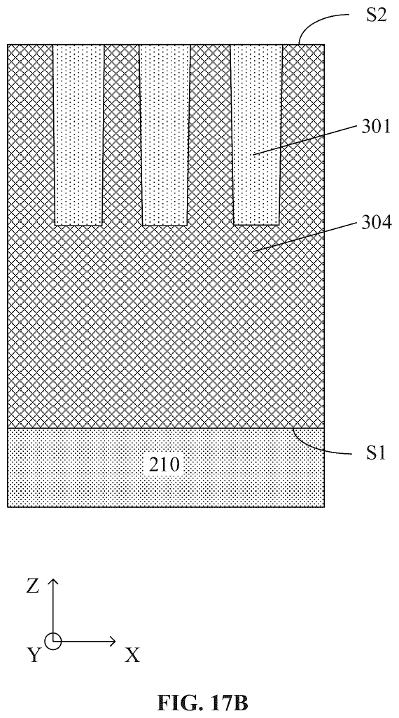

The substrate is thinned along the first surface. The method for thinning includes, but is not limited to, dry etching, wet etching, CMP, or the like, until the first end of the conductive channel 301 of the transistor in the substrate is exposed. The first end of the conductive channel is exposed after thinning as shown in FIGS. 17A and 17B. FIG. 17A is a sectional view of the semiconductor structure in the direction of the to-be-formed bit line, and FIG. 17B is a sectional view of the semiconductor structure in the direction in parallel with the word line structure 307. The direction of the to-be-formed bit line may be perpendicular to the formation direction of the word line structure 307.

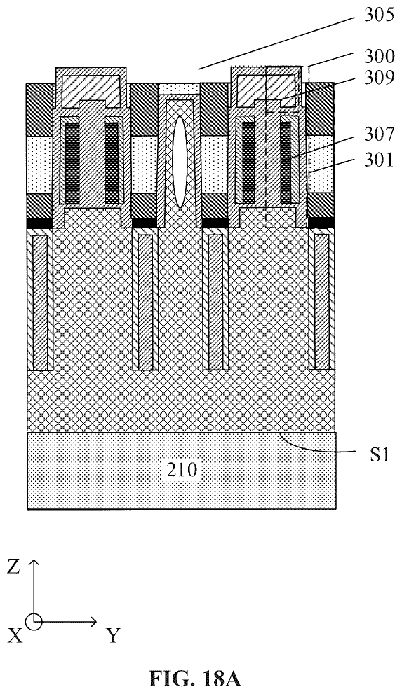

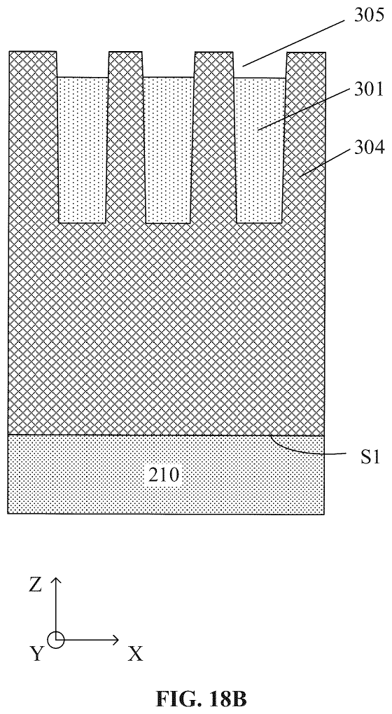

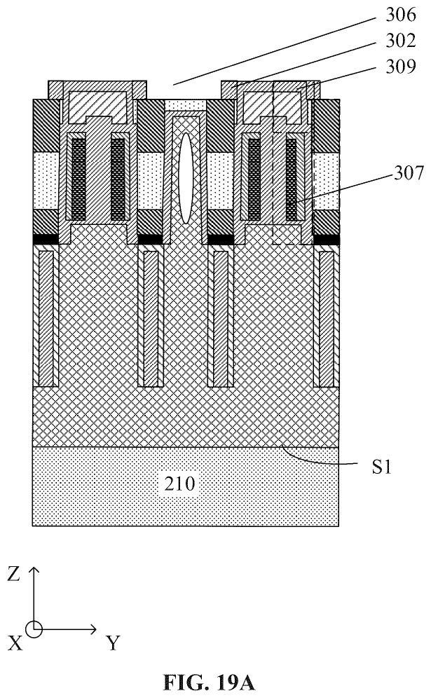

The conductive channel 301 of the transistor is then etched continuously to form the recessed structure 305 as shown in FIGS. 18A and 18B. FIG. 18A is a sectional view of the semiconductor structure in the direction of the to-be-formed bit line, and FIG. 18B is a sectional view of the semiconductor structure in the direction in parallel with the word line. The direction of the to-be-formed bit line may be perpendicular to the formation direction of the word line structure 307. As shown in FIG. 18A, the depth of the recessed structure 305 positioned on the word line structure 307 is less than the depth of the recessed structure 305 positioned on the conductive channel 301. This is because after the substrate on the word line structure 307 has been etched completely, the isolation layer 309 in the word line structure 307 is taken as the etching stop layer, but there is no isolation layer taken as the etching stop layer on the first end D1 of the conductive channel 301. Thus, the etched depth of the first end of the conductive channel 301 is deeper than the etched depth of the region on which the word line structure 307 is positioned. As shown in FIG. 18B, there is a recessed structure 305 between the dielectric layers 304. This is because in case of etching downwardly, it is selected to form the recessed structure 305 on the formation region of the transistor, that is, on the word line structure 307 and the conductive channel 301, such that a bit line structure may be formed in the recessed structure 305 subsequently, instead of forming the bit line structure on the dielectric layer 304. Therefore, there is no need to etch the dielectric layer 304 downwardly.

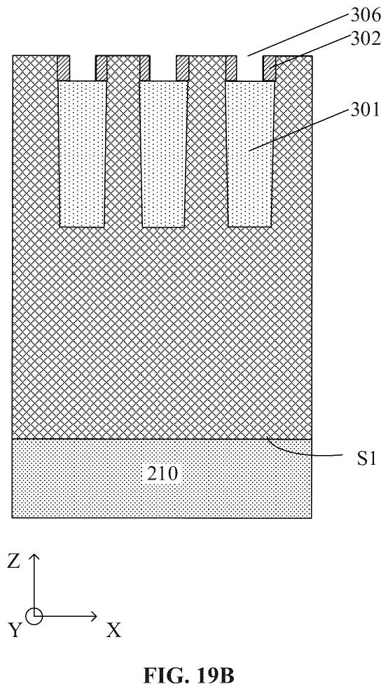

FIG. 19A is a sectional view of the semiconductor structure in the direction of the to-be-formed bit line, and FIG. 19B is a sectional view of the semiconductor structure in the direction in parallel with the word line structure 307. As shown in FIGS. 19A and 19B, the insulation layer 302 is formed on at least one of the opposite sidewalls of the recessed structure 305, and the insulation layer 302 covers a portion of the word line structure 307 and covers at least a portion of the first end of the conductive channel 301. The material of the insulation layer 302 may be the same as that of the dielectric layer 304. The trench 306 is formed after the sidewall of the recessed structure 305 is covered by the insulation layer, and the trench 306 has a width narrower than the recessed structure 305.

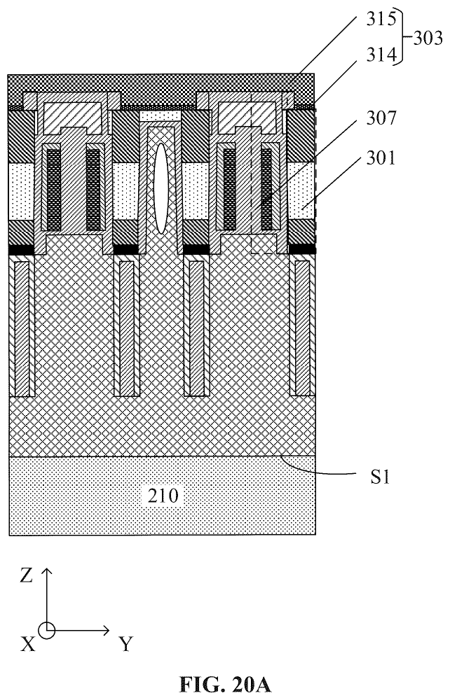

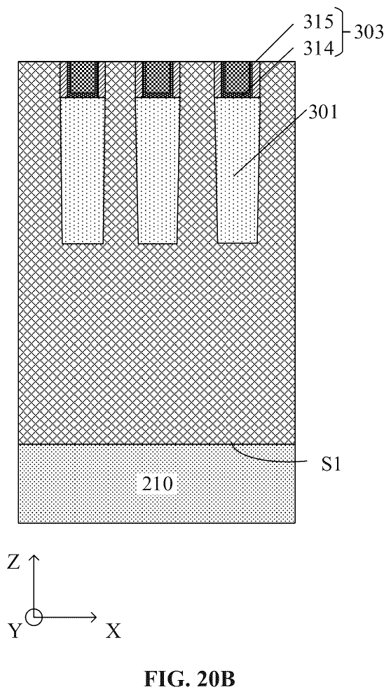

FIG. 20A is a sectional view of the semiconductor structure in the direction of forming the bit line, and FIG. 20B is a sectional view of the semiconductor structure in the direction in parallel with the word line structure. As shown in FIGS. 20A and 20B, one or more of a polysilicon layer, a metal silicide layer 314 (for example, a titanium nitride layer), and a metal layer 315 (for example, tungsten) are sequentially deposited in the trench 306 to form the bit line structure 303. During the actual process of depositing the bit line material, the bit line material generally covers the upper surface of the insulation layer 302. Therefore, after the bit line material has been deposited, it is necessary to perform a CMP process on the upper surface of the insulation layer 302 until the insulation layer 302 is exposed.

The bit line structure 303 is formed in the trench on the conductive channel, so as to solve the problem of aligning the bit line and the active region. Furthermore, the size of the bit line channel is reduced by a sidewall deposition/etching process after etching backing of the backside substrate, thereby reducing the key size of the bit line, reducing the parasitic capacitance between the bit lines, and improving the reading performance of the DRAM. Furthermore, the bit line structure in the embodiments of the disclosure is formed directly on the bit line structure, which will not result in alignment failure due to the overall warping and local stress of the substrate. The problem of alignment failure between the bit line and the source is solved.

It should be understood that references throughout the specification to “one embodiment” or “an embodiment” mean that a particular feature, structure or characteristic associated with the embodiment is included in at least one embodiment of the disclosure. Thus, the words “in an embodiment” or “in some embodiments” appearing throughout the specification do not necessarily refer to the same embodiment. Furthermore, these particular features, structures or characteristics may be combined in one or more embodiments in any suitable manner. It should be understood that in the various embodiments of the disclosure, the serial numbers of the above processes do not imply the order of execution, and the order of execution of the processes should be determined by their function and inherent logic, and should not constitute any limitation to the implementation processes of the embodiments of the disclosure. The above serial numbers of the embodiments of the disclosure are only for description and do not represent the advantages and disadvantages of the embodiments.

It should be noted that, in the disclosure, the terms “comprising”, “including” or any other variations thereof are intended to encompass non-exclusive inclusion, so that a process, method, object or device which includes various elements includes not only those elements but also other elements that are not explicitly listed, or elements inherent in the process, method, object or device. Without further limitations, an element defined by the phrase “including a . . . ” does not exclude the existence of another identical element in the process, method, object or device which includes the element.

The above descriptions are only implementation manners of the disclosure, but the scope of protection of the disclosure is not limited thereto. Any variation or substitution which may be readily thought by those skilled in the art within the technical scope disclosed in the disclosure should fall within the scope of protection of the disclosure. Therefore, the scope of protection of the disclosure should be subject to the scope of protection of the claims.

### INDUSTRIAL APPLICABILITY

According to the embodiments of the disclosure, the size of the bit line channel is reduced by a sidewall deposition/etching process after etching backing of the backside substrate, thereby reducing the key size of the bit line, reducing the parasitic capacitance between the bit lines, and improving the reading performance of the transistor. Furthermore, the bit line structure in the embodiments of the disclosure is formed directly on the bit line structure, which will not result in alignment failure due to the overall warping and local stress of the substrate. The probability of alignment failure between the bit line and the source is reduced.

1. A method for manufacturing a semiconductor structure, comprising:
providing a substrate having a first surface and a second surface that are opposite to each other;
forming a transistor array positioned in the substrate from the first surface of the substrate, wherein the transistor array includes a plurality of transistors, and a height of each transistor is less than a thickness of the substrate;
thinning the substrate from the second surface until a first end of a conductive channel of each transistor is exposed, wherein the first end is an end, which is close to the second surface, of the conductive channel;
forming an insulation layer covering at least a portion of the first end of the conductive channel, such that a first width of an exposed portion of the first end of the conductive channel is less than a second width of the conductive channel; and
forming a bit line structure covering the exposed portion of the first end of the conductive channel.

2. The method of claim 1, wherein a dielectric layer is filled between the plurality of transistors, and the forming the insulation layer covering at least the portion of the first end of the conductive channel comprises:
continuing to etch, after the substrate is thinned, a portion of the conductive channel from the first end of the conductive channel, to form a plurality of recessed structures between the dielectric layers; and
forming the insulation layer on a sidewall of the recessed structure, such that the insulation layer covers at least the portion of the first end of the conductive channel to form a trench with a sidewall covered by the insulation layer.

3. The method of claim 2, wherein the forming the insulation layer on the sidewall of the recessed structure comprises:
covering a bottom surface and the sidewall of the recessed structure by an insulation material; and
removing the insulation material covering the bottom surface of the recessed structure to form the insulation layer covering the sidewall of the recessed structure.

4. The method of claim 2, wherein there is a word line structure of a transistor between two adjacent conductive channels, the word line structure is positioned in a region of the recessed structure, and a depth of the recessed structure positioned on the word line structure is less than a depth of the recessed structure positioned on the conductive channel;
wherein the forming the insulation layer on a sidewall of the recessed structure comprises:
forming, in the recessed structure, the insulation layer covering a portion of the word line structure and covering at least the portion of the first end of the conductive channel.

5. The method of claim 4, wherein the forming the bit line structure covering the exposed portion of the first end of the conductive channel comprises:
depositing a conductive material in the trench to form the bit line structure, wherein a width of the trench is equal to the first width.

6. The method of claim 1, comprising:
providing a carrier wafer; and
bonding the first surface of the substrate and the carrier wafer.

7. The method of claim 6, wherein the thinning the substrate from the second surface until the first end of the conductive channel of the transistor is exposed comprises:
flipping the carrier wafer and the substrate, such that the second surface is vertically upward; and
thinning the substrate from the second surface until the first end of the conductive channel of the transistor is exposed.

8. The method of claim 1, comprising:
forming, on the first surface of the substrate, a storage capacitor connected to the transistor.

9. The method of claim 1, comprising:
forming a drain at the first end of the conductive channel; and
forming a source at a second end of the conductive channel, wherein the second end is an end, which is close to the first surface, of the conductive channel.

10. A semiconductor structure, comprising:
a substrate, wherein the substrate has a first surface and a second surface that are opposite to each other;
a transistor array positioned in the substrate, wherein the transistor array includes a plurality of transistors;
an insulation layer, covering at least a portion of a first end of a conductive channel, such that a first width of a portion of the first end of the conductive channel, which is not covered by the insulation layer, is less than a second width of the conductive channel, wherein the first end is an end, which is close to the second surface, of the conductive channel; and
a bit line structure, connected to the portion of the first end of the conductive channel, which is not covered by the insulation layer.

11. The semiconductor structure of claim 10, comprising:
dielectric layers positioned between the plurality of transistors; and
a plurality of recessed structures positioned between the dielectric layers.

12. The semiconductor structure of claim 11, wherein the insulation layer is positioned on a sidewall of the recessed structure, the insulation layer covers at least the portion of the first end of the conductive channel, and the recessed structure with the sidewall covered by the insulation layer is a trench.

13. The semiconductor structure of claim 12, wherein the bit line structure is positioned in the trench, and a width of the trench is equal to the first width.

14. The semiconductor structure of claim 11, comprising:
a word line structure of the transistor, wherein the word line structure is positioned between two adjacent conductive channels, the word line structure is positioned in a region of the recessed structure, and a depth of the recessed structure positioned on the word line structure is less than a depth of the recessed structure positioned on the conductive channel.

15. The semiconductor structure of claim 10, comprising:
a storage capacitor, positioned on the first surface of the substrate and connected to the transistor.

16. The semiconductor structure of claim 10, wherein the first end of the conductive channel comprises:
a drain of the transistor; and
a second end of the conductive channel comprises:
a source of the transistor, and the second end is an end, which is close to the first surface, of the conductive channel.
